(19) United States
(12) Patent Application Publication
(10) Pub. No.: US 2015/0034372 A1
(43) Pub. Date: Feb. 5, 2015

(54) CIRCUIT BOARD

(71) Applicants: HON HAI PRECISION INDUSTRY CO., LTD., New Taipei (TW); HONG GU JIN PRECISION INDUSTRY (ShenZhen) CO., LTD, Shenzhen (CN)

(72) Inventors: MENG-LONG FENG, Shenzhen (CN); XIAO-CONG WEI, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhe (CN)

(21) Appl. No.: 14/102,472

(22) Filed: Dec. 10, 2013

(30) Foreign Application Priority Data
Aug. 1, 2013 (CN) 2013103317998

(51) Int. Cl. H05K 1/02

(52) U.S. Cl. CPC H05K 1/0296
USPC 174/257

(57) ABSTRACT

A circuit board for preventing pins of inserting components from being short-circuited during the welding process welding is provided. The circuit board includes an insulating base board comprising a base plate and at least one column of via set on the insulating base board. A plurality of copper foil rings are set on the base plate. An insulating dielectric layer is covered on the base plate and the plurality of copper foil rings. A plurality of solder mask openings are set on the insulating dielectric layer, each solder mask opening is shaped as a circular hole, and is concentric with one via. By covering the insulating dielectric layer on the copper foil rings, an adherence of copper foil and the insulating base board increases, thereby pins of the inserting components will not be easily disengaged from the copper foil in the insulating base board.

### BACKGROUND

1. Technical Field

The present disclosure relates to circuit boards, and particularly to a circuit board for preventing pins of inserting components from being short-circuited during welding.

2. Description of Related Art

In conventional circuit boards, adherence between copper foil and baseboard material is poor. The pins of inserting components can easily disengage from the copper foil in the baseboard, which can cause a short circuit during welding.

Therefore, it is desirable to provide a circuit board preventing pins of inserting components from being short-circuited during welding.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is a schematic view of an embodiment of a circuit board preventing pins of inserting components from being short-circuited during welding.

FIG. 2 is a cross-sectional view of the circuit board of FIG. 1 through II-II line.

### DETAILED DESCRIPTION

Embodiments of the present disclosure will be described with reference to the drawings.

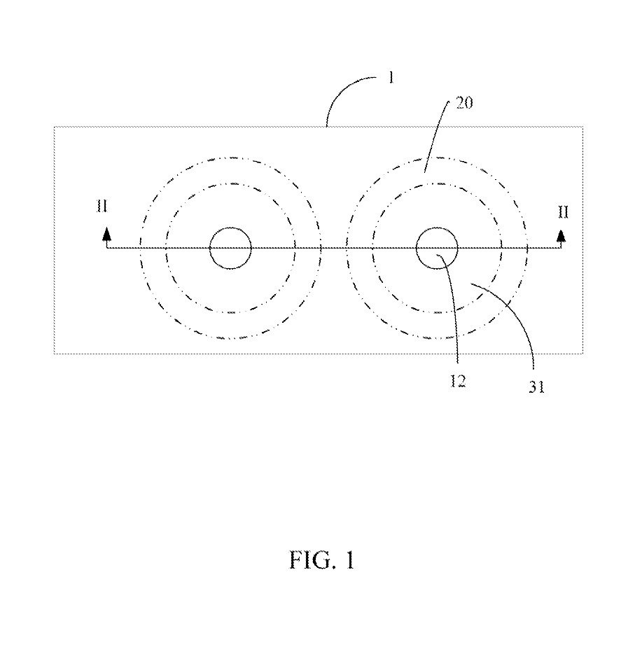

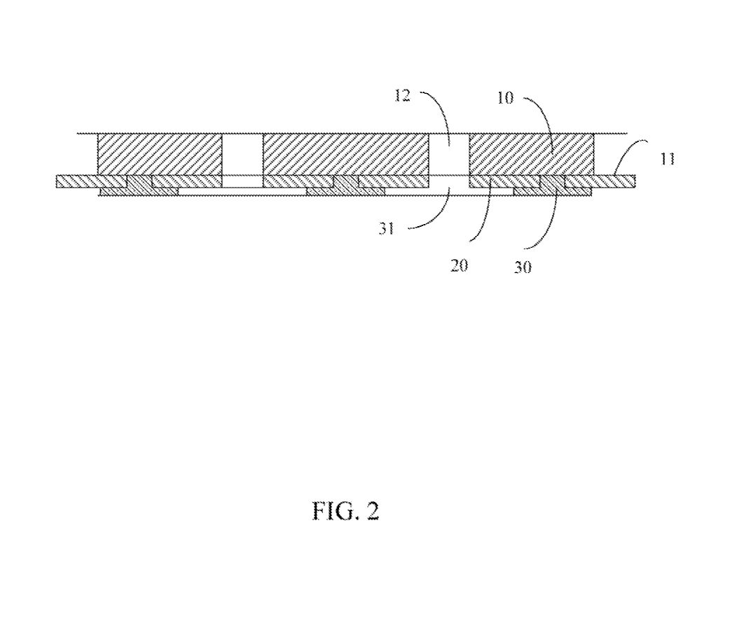

FIG. 1 is a schematic view of an embodiment of a circuit board 1 preventing pins of inserting components from being short-circuited during welding. Referring also to FIG. 2, the circuit board 1 includes an insulating base board 10, several copper foil rings 20 set on the insulating base board 10, and an insulating dielectric layer 30. The insulating base board 10 includes a base plate 11. There is at least one column of vias 12 set on the insulating base board 10. A diameter of each via 12 can be about 0.4 mm. In each column of vias 12, an interval between two adjacent vias 12 can be about 2 mm.

The several copper foil rings 20 are set on the base plate 11. An interior diameter of each copper foil ring 20 can be about 0.4 mm, and an external diameter of each copper foil ring 20 can be about 1.75 mm. Each copper foil ring 20 can be concentric with one via 12, and the interior diameter of each copper foil ring 20 is about the same as the diameter of a corresponding via 12.

The insulating dielectric layer 30 covers the base plate 11 and the several copper foil rings 20. Several solder mask openings 31 are set on the insulating dielectric layer 30. Each solder mask opening 31 can be shaped as a circular hole, and concentric with one via 12. A diameter of each solder mask openings 31 can be about 1.25 mm.

By covering the insulating dielectric layer 30 on the copper foil rings 20, an adherence of the copper foil and the insulating base board 10 increases, pins of the inserting components will not easily disengage from the copper foil in the insulating base board 10. Because the insulating dielectric layer 30 is not conductive, the circuit board 1 will not be short-circuited during welding and damaged.

It will be understood that the above particular embodiments are shown and described by way of illustration only. The principles and the features of the present disclosure may be employed in various and numerous embodiments thereof without departing from the scope of the disclosure. The above-described embodiments illustrate the possible scope of the disclosure but do not restrict the scope of the disclosure.

What is claimed is:

1. A circuit board preventing pins of inserting components from being short-circuited during welding, the circuit board comprising:
an insulating base board comprising a base plate and at least one via set in the insulating base board;
a plurality of copper foil rings set on the base plate, wherein each copper foil ring is concentric with the at least one via, an interior diameter of each copper foil ring is substantially the same as a diameter of a corresponding via; and
an insulating dielectric layer covering a portion of the base plate and the copper foil rings, wherein a plurality of solder mask openings are defined in the insulating dielectric layer, and each solder mask opening is shaped as a circular hole, and concentric with the at least one via.

2. The circuit board of claim 1, wherein the diameter of each via is about 0.4 mm, and an interval between two adjacent vias is about 2 mm.

3. The circuit board of claim 1, wherein an interior diameter of each copper foil ring is about 0.4 mm, and an external diameter of each copper foil ring is about 1.75 mm.

4. The circuit board of claim 1, wherein the diameter of each solder mask openings is about 1.25 mm.
